(19) United States
(12) Patent Application Publication
(10) Pub. No.: US 2003/0025554 A1
(43) Pub. Date: Feb. 6, 2003

(54) Headphone amplifier

(75) Inventor: Masao Noro, Hamamatsu-shi (JP)

Correspondence Address: PILLSBURY MADISON & SUTRO LLP, 725 South Figueroa, Suite 1200, Los Angeles, CA, 90017-5443, US

(73) Assignee: Yamaha Corporation, Hamamatsu-shi (JP)

(21) Appl. No.: 10/207,487

(22) Filed: Jul. 29, 2002

(30) Foreign Application Priority Data
Jul. 31, 2001 (JP) P2001-232429

(51) Int. Cl. H03F 1/36

(52) U.S. Cl. 330/109

(57) ABSTRACT

An input signal from a signal source (10) is applied to an amplifier (20) via an input coupling capacitor (C_{IN}). An output signal from the amplifier (20) is supplied to a headphone (30) via an output coupling capacitor (C₁), and negatively fed back by a first negative feedback circuit configured by resistors (R₂, R₁), and a capacitor (C_{NF}). A second negative feedback circuit configured by a capacitor (C₂) and a resistor (R₃) is disposed between the output of the capacitor (C₁) and the terminal of the amplifier (20). When a capacitor which is sufficiently smaller in capacitance than the capacitor (C₁) is used as the capacitor (C₂), the capacitance of the capacitor (C₁) can be made smaller than that of a capacitor used in the conventional art and the frequency characteristics in a low-frequency band can be enhanced.

### BACKGROUND OF THE INVENTION

The present invention relates to a headphone amplifier which is suitably used in a mobile terminal such as a portable telephone.

FIGS. 5 and 6 are circuit diagrams schematically showing the configurations of conventional headphone amplifiers which are used in a portable telephone. FIG. 5 shows a headphone amplifier of the output coupling capacitor type, and FIG. 6 shows a headphone amplifier of the center amplifier type.

In the output coupling capacitor type of FIG. 5, an input signal from an R-channel signal source 10A is amplified by an amplifier 20A via a coupling capacitor C_{1N1} for DC cut, and the amplified output signal is supplied to a headphone 30A via a coupling capacitor C₁₁.

An input signal from an L-channel signal source 10B is amplified by an amplifier 20B via a coupling capacitor C_{IN2} for DC cut, and the amplified output signal is supplied to a headphone 30B via a coupling capacitor C₁₂.

The amplifiers 20A and 20B are connected between a power source voltage +V_{DD} and the grounding potential. Each of the amplified outputs is a signal which oscillates about ½V_{DD}. In each of the headphones 30A and 30B, one terminal is connected to the coupling capacitor C₁₁or C₁₂ via a headphone terminal 40A or 40C, and the other terminal is connected commonly to a grounding terminal 40B.

In the center amplifier type of FIG. 6, an input signal from an R-channel signal source 10A is amplified by an amplifier 20A via a coupling capacitor C_{IN1}, and an amplified output signal is supplied to a headphone 30A.

An input signal from an L-channel signal source 10B is amplified by an amplifier 20C via a coupling capacitor C_{IN2}, and an amplified output signal is supplied to a headphone 30B.

The amplifiers 20A and 20C are connected between a power source voltage +V_{DD} and the grounding potential. Each of the amplified outputs is a signal which oscillates about ½V_{DD}. In each of the headphones 30A and 30B, one terminal is connected to the output terminal of the amplifier 20A or 20C via a headphone terminal 40A or 40C, and the other terminal is connected commonly to a terminal 40B. A voltage ½V_{DD} is applied to the terminal 40B via an amplifier 20B.

In the output coupling capacitor type of FIG. 5, since the headphones 30A and 30B have an impedance as low as 16 Ω, the coupling capacitors C₁₁ and C₁₂ are required to have a large capacitance (for example, 220 μF) in order to reproduce a low-frequency band. In a small device such as a portable telephone, consequently, there arises a problem in that a space for mounting capacitors of a large capacitance is necessary, and therefore the size of the device is increased.

In the center amplifier type of FIG. 6, coupling capacitors are not necessary. In a portable telephone, however, the headphone terminals 40A, 40B, and 40C are often used also as terminals for a headset (a microphone +an earphone). In this case, the potential of ½V_{DD} is applied to the headphone terminal 40B, and hence there arises a problem in that a microphone cannot be connected to the terminal.

### SUMMARY OF THE INVENTION

The invention has been conducted in view of the above circumstances. It is an object of the invention to provide a headphone amplifier which is of the output coupling capacitor type, and in which the capacitance of an output coupling capacitor can be reduced.

In order to attain the object, the headphone amplifier of the invention is a headphone amplifier which has an amplifier for amplifying an input signal, and in which an amplified output signal is negatively fed back to an input side of the amplifier via a first negative feedback circuit, and is supplied to a headphone via a first capacitor for DC cut, wherein a second negative feedback circuit which is configured by a series circuit of a second capacitor and a resistor is connected between an output side of the first capacitor and the input side of the amplifier.

According to the invention, when the capacitance of the second capacitor is selected to be smaller than that of the first capacitor, the capacitance of the first capacitor can be made smaller than that of a capacitor used in the conventional art. Furthermore, it is possible to obtain frequency characteristics which are a combination of the frequency characteristics of the second negative feedback circuit, and those of the conventional art, so that the frequency characteristics in a low-frequency band can be enhanced.

### BRIEF DESCRIPTION OF THE DRAWINGS

FIG. 1 is a circuit diagram showing the configuration of a headphone amplifier which is a first embodiment of the invention.

FIG. 2 is a circuit diagram showing a headphone amplifier which is a second embodiment of the invention.

FIG. 3 is a characteristic diagram showing an example of frequency characteristics and illustrating effects of the first and second embodiments in comparison to a conventional circuit.

FIG. 4 is a circuit diagram showing the configuration in the case where a headphone amplifier which is a third embodiment of the invention is used in a mobile terminal.

FIG. 5 is a circuit diagram showing the configuration of a conventional headphone amplifier of the output coupling capacitor type.

FIG. 6 is a circuit diagram showing the configuration of a conventional headphone amplifier of the center amplifier type.

### DETAILED DESCRIPTION OF PREFERRED EMBODIMENTS

Hereinafter, embodiments of the invention will be described with reference to the accompanying drawings.

FIG. 1 is a circuit diagram showing the configuration of a headphone amplifier according to a first embodiment of the invention. In the embodiment, the invention is applied to a headphone amplifier of the above-described output coupling capacitor type of FIG. 5, and the configuration of one (R- or L-channel) of the channels of FIG. 5 is shown.

Referring to FIG. 1, an input signal from a signal source 10 is applied to the plus terminal of an amplifier 20 via an input coupling capacitor C_{IN}. The amplifier 20 is an in-phase amplifier which is connected between a power source voltage V_{DD} and the grounding potential. A first negative feedback circuit configured by resistors R₂ and R₁, and a capacitor C_{NF} is disposed between the output terminal and the minus terminal of the amplifier 20. A bias voltage of ½V_{DD} is applied to the plus terminal via a resistor R₄. The output signal amplified by the amplifier 20 is supplied to a headphone 30 via an output coupling capacitor C₁.

The embodiment has the circuit configuration described above, and is characterized in that the signal which has passed through the capacitor C₁ is negatively fed back to the minus terminal of the amplifier 20 via a second negative feedback circuit that is configured by a series circuit of a capacitor C₂ and a resistor R₃. A capacitor which is sufficiently smaller in capacitance than the capacitor C₁ is used as the capacitor C₂. For example, the capacitor C₁ is 100 μF, and the capacitor C₂ is 0.1 μF.

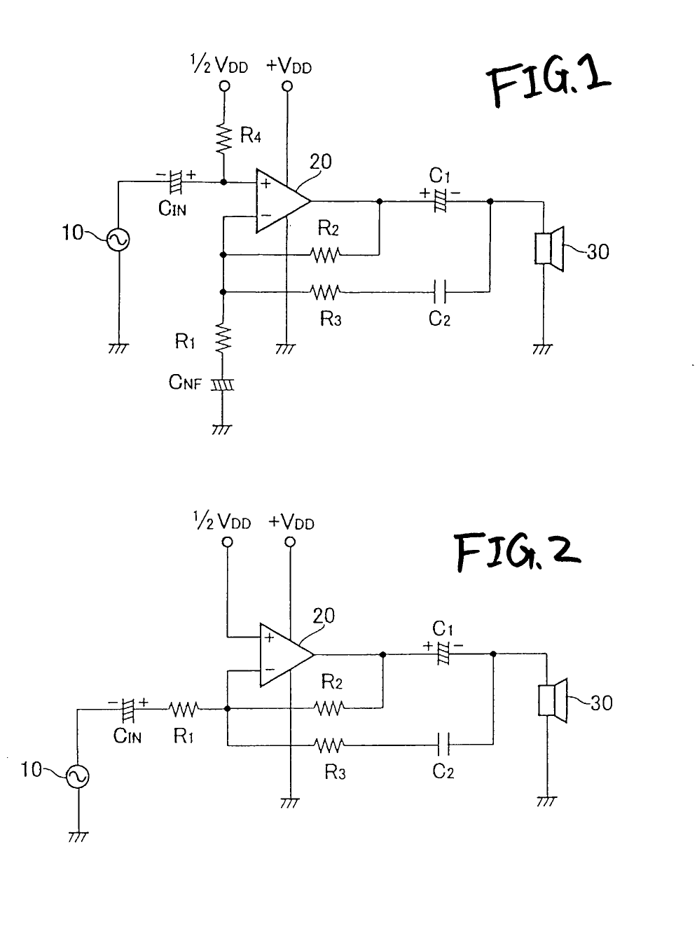

FIG. 2 is a circuit diagram showing a headphone amplifier according to a second embodiment of the invention.

In the embodiment, an inverting amplifier is used as an amplifier 20. An input signal from a signal source 10 is applied to the minus terminal of the amplifier 20 via a capacitor C_{IN} and a resistor R₁, and the output signal of the amplifier 20 is negatively fad back via a resistor R₂.

The other portions are configured in the same manner as those of FIG. 1. In the same manner as the first embodiment, the embodiment is configured so that the signal which has passed through the capacitor C₁ is negatively fed back to the minus terminal of the amplifier 20 via a second negative feedback circuit that is configured by a capacitor C₁ and a resistor R₃.

FIGS. 1 and 2 show the circuit configurations in the case of a one-channel system. When a two-channel system is to be configured, two circuits which are similarly configured are disposed in parallel.

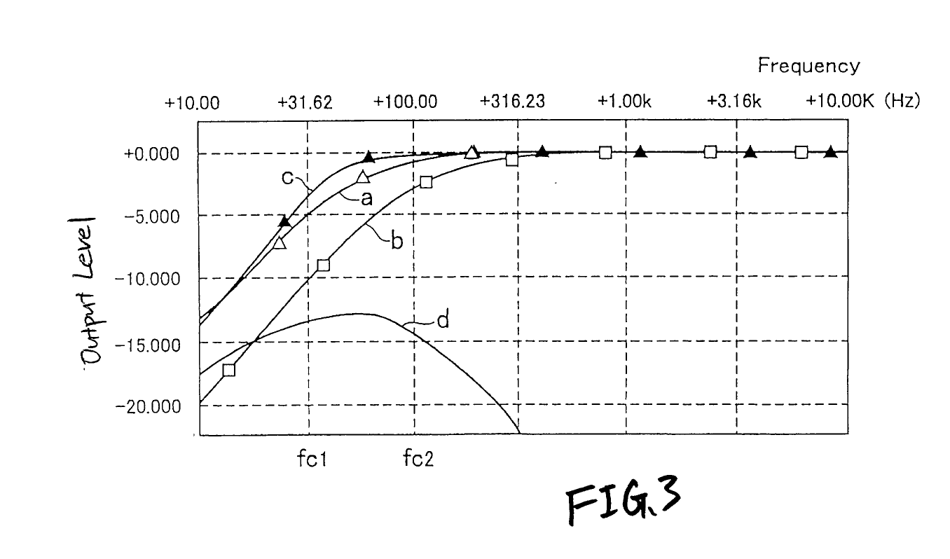

FIG. 3 shows an example of frequency characteristics and illustrating effects of the first and second embodiments in comparison to the conventional circuit. The frequency characteristics were obtained in the case where the values of the components in FIGS. 1 and 2 were set as follows: R₁=25 kΩ, R₂=50 kΩ, R₃=50 kΩ, C₂=0.1 μF, and hp (the impedance of the headphone 30) =16 Ω.

In FIG. 3, the curve a shows the frequency characteristics of the conventional circuit in the case where the second negative feedback circuit configured by C₂ and R₃ is not disposed and C₁=220 μF. The curve b shows the frequency characteristics in the case where the second negative feedback circuit is not disposed and C₁=100 μF. The curve c shows the frequency characteristics according to the invention in the case where the second negative feedback circuit is disposed and C₁=100 μF. The curve d shows the frequency characteristics of the second negative feedback circuit.

The cut-off frequency fc1 in the curve c is determined by the values of C₂ and R₃, and fc1 =½πC₂·R₃. The frequency fc1 is lower than the cut-off frequency fc2 =½πC₁·hp in the curve a. The curve b shows the case where the conventional circuit is simply modified so that the capacitance of C1 is reduced from 220 μF to 100 μF. Therefore, it will be seen that the curve c is obtained by combining the characteristics of the curves b and d to each other, and the frequency characteristics in a low-frequency band is enhanced by disposing the second negative feedback circuit according to the invention.

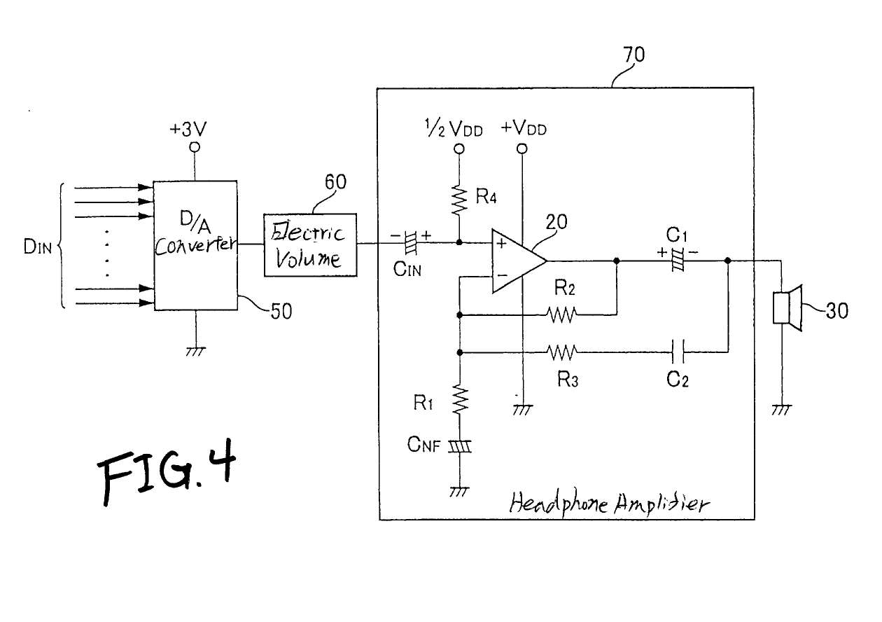

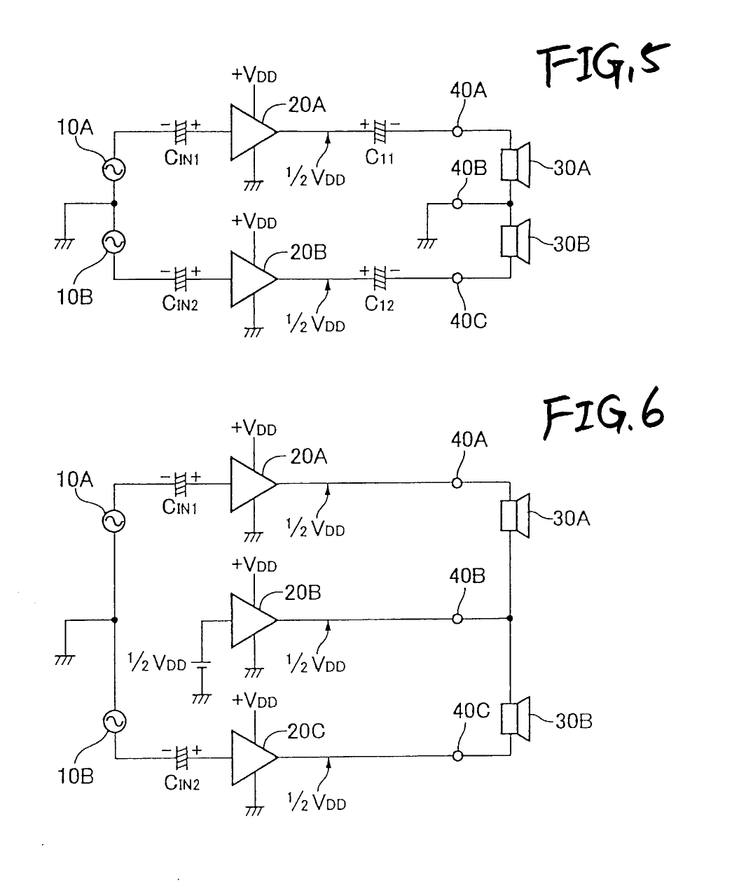

FIG. 4 shows a third embodiment of the invention in which the circuit of the first embodiment shown in FIG. 1 is disposed in a mobile terminal such as a portable telephone.

Referring to FIG. 4, an input data D_{IN} of, for example, 16 bits is converted by a D/A converter 50 into, for example, an analog signal of an amplitude of 0 to 3 V and centered at 1.5 V. The analog signal is subjected to a volume adjustment in an electronic volume control 60, amplified by a headphone amplifier 70 according to the invention, and then supplied to the headphone 30.

The circuit of FIG. 1 is used as the headphone amplifier 70. It is a matter of course that the circuit of FIG. 2 may be used as the headphone amplifier. The headphone amplifier 70 can be configured into a one-chip LSI. In this case, the capacitors C₁ and C₂ and the resistors R₂ and R₃ are connected to the amplifier through a connecting terminal (not shown).

As described above, according to the invention, since an output signal which has passed through an output coupling capacitor of an amplifier is negatively fed back to the amplifier via a capacitor and a resistor, the capacitance of the output coupling capacitor can be reduced, for example, from 220 μF to 100 μF. According to this configuration, when the amplifier is used in a mobile terminal such as a portable telephone, the size of the terminal can be reduced. For example, the height of a case can be reduced by several millimeters. Furthermore, the reproduction characteristics in a low-frequency band can be improved.

What is claimed is:

1. A headphone amplifier comprising:
an amplifier for amplifying an input signal and outputting an amplified signal as an output signal;
a first negative feedback circuit for negatively feeding back the output signal to an input side of the amplifier;
a first capacitor disposed between an output side of the amplifier and a headphone, thereby the output signal is supplied to the headphone through the first capacitor; and
a second negative feedback circuit which includes a series circuit of a second capacitor and a resistor and feeds back the output signal, supplied from the first capacitor to the headphone, to the input side of the amplifier.

2. The headphone amplifier according to claim 1, wherein a capacitance of the second capacitor is smaller than that of the first capacitor.

3. The headphone amplifier according to claim 1, wherein the amplifier is one of an in-phase amplifier and an inverting amplifier.

4. The headphone amplifier according to claim 1, wherein the amplifier is connected between a positive or negative power source and a grounding potential.

5. The headphone amplifier according to claim 1, wherein the headphone amplifier is configured into a one-chip integrated circuit.

6. The headphone amplifier according to claim 1, wherein the headphone amplifier is used in a mobile terminal.
